(19) United States
(12) Patent Application Publication
(10) Pub. No.: US 2025/0240935 A1
(43) Pub. Date: Jul. 24, 2025

(54) COMPONENT MOUNTING EQUIPMENT

(71) Applicant: Samsung Electronics Co., Ltd., Suwon-si (KR)

(72) Inventors: Sangmyung LEE, Suwon-si (KR); Hyundong KIM, Changwon-si (KR); Jepil LEE, Changwon-si (KR)

(73) Assignees: Samsung Electronics Co., Ltd., Suwon-si (KR); Hanwha Precision Machinery Co., Ltd., Changwon-si (KR)

(21) Appl. No.: 19/010,666

(22) Filed: Jan. 6, 2025

(30) Foreign Application Priority Data
Jan. 22, 2024 (KR) 10-2024-0009789

(51) Int. Cl. H05K 13/04; H05K 13/08

(52) U.S. Cl. CPC H05K 13/0495; H05K 13/046; H05K 13/0478; H05K 13/0882

(57) ABSTRACT

Component mounting equipment includes a first transfer line, a second transfer line, and a surface mounting equipment on the first transfer line and the second transfer line. The surface mounting equipment includes a first mounting head, a second mounting head, and a controller. The controller is configured to control the surface mounting equipment so that the surface mounting equipment performs continuous mounting. In the continuous mounting, the surface mounting equipment is configured to perform either separate mounting or collaborative mounting while giving priority to the separate mounting. Through the component mounting equipment, it is possible to automatically perform continuous mounting and preceding mounting based on the order of substrates detected on the first transfer line and the second transfer line, thereby reducing delays and congestion in mounting operations.

### CROSS-REFERENCE TO RELATED APPLICATION

This application is based on and claims priority under 35 U.S.C. § 119 to Korean Patent Application No. 10-2024-0009789, filed on Jan. 22, 2024, in the Korean Intellectual Property Office, the disclosure of which is incorporated by reference herein in its entirety.

### BACKGROUND

The inventive concepts relate to component mounting equipment.

Surface mount technology (SMT) refers to a technique commonly used during printed circuit board (PCB) processes. PCBs tend to become smaller, thinner, and more lightweight, and when the PCBs are densely packed and highly functional, there is a need for techniques for quickly and accurately mounting various electronic components on the PCBs. Accordingly, the SMT allowing surface-mounted components to be placed and bonded on the surface of the PCB is increasingly important in the assembly of semiconductor products.

### SUMMARY

The inventive concepts aim at improving the productivity of a component mounting operation through the use of component mounting equipment.

Technical problems to be solved by the inventive concepts are not limited to the above description, and other technical problems may be clearly understood by one of ordinary skill in the art from the descriptions provided hereinafter.

According to an example embodiment of the inventive concepts, component mounting equipment may include a first transfer line, a second transfer line spaced apart from the first transfer line, a first surface mounting equipment on the first transfer line and the second transfer line, wherein the first surface mounting equipment includes a first mounting head that is adjacent to the first transfer line, a second mounting head that is adjacent to the second transfer line, and a first controller configured to control the first mounting head and the second mounting head, the first controller is further configured to control the first surface mounting equipment to perform continuous mounting, in the continuous mounting, the first surface mounting equipment is configured to perform either separate mounting or collaborative mounting but give priority to the separate mounting, the separate mounting is an operation in which each of the first mounting head and the second mounting head is configured to perform a main mounting operation on a main substrate, the collaborative mounting is an operation in which one of the first mounting head and the second mounting head is configured to perform a main mounting operation on a single substrate, while the other one of the first mounting head or the second mounting head is configured to simultaneously perform a sub-mounting operation on the single substrate, the main mounting operation is an operation in which the first mounting head is configured to perform an operation on a main substrate placed on the first transfer line or the second mounting head is configured to perform an operation on a main substrate placed on the second transfer line, the sub-mounting operation is an operation in which the first mounting head is configured to perform an operation on a sub-substrate placed on the second transfer line or the second mounting head is configured to perform an operation on a sub-substrate placed on the first transfer line, the main substrate includes a substrate placed on the first transfer line with respect to the first mounting head or a substrate placed on the second transfer line with respect to the second mounting head, and the sub-substrate includes a substrate placed on the second transfer line with respect to the first mounting head or a substrate placed on the first transfer line with respect to the second mounting head.

According to an example embodiment of the inventive concepts, component mounting equipment may include a first transfer line, a second transfer line parallel to the first transfer line, the second transfer line being separate from the first transfer line in a lateral direction, a first surface mounting equipment on the first transfer line and the second transfer line, and a second surface mounting equipment arranged on the first transfer line and the second transfer line, the second surface mounting equipment and being next to the first surface mounting equipment, wherein the first surface mounting equipment includes a first mounting head that is adjacent to the first transfer line, a second mounting head that is adjacent to the second transfer line, and a first controller configured to control the first mounting head and the second mounting head of the first surface mounting equipment, the second surface mounting equipment includes a first mounting head that is adjacent to the first transfer line, a second mounting head that is adjacent to the second transfer line, and a second controller configured to control the first mounting head and the second mounting head of the second surface mounting equipment, and when the second surface mounting equipment stops working, the first controller is further configured to control the first surface mounting equipment to perform preceding mounting, the preceding mounting is performed by the first mounting head of the first surface mounting equipment as a main mounting operation to which a main mounting operation of the first mounting head of the second surface mounting equipment is added, and the main mounting operation includes an operation in which the first mounting head of the first surface mounting equipment or the first mounting head of the second surface mounting equipment performs an operation on a main substrate placed on the first transfer line or an operation in which the second mounting head of the first surface mounting equipment or the second mounting head of the second surface mounting equipment performs an operation on a main substrate placed on the second transfer line.

According to an example embodiment of the inventive concepts, component mounting equipment may include a first transfer line, a second transfer line parallel to the first transfer line, the second transfer line being separate separated therefrom from the first transfer line in a lateral direction, a first surface mounting equipment on the first transfer line and the second transfer line, and a second surface mounting equipment on the first transfer line and the second transfer line, the second surface mounting equipment being next to the first surface mounting equipment, wherein the first surface mounting equipment includes a first mounting head that is adjacent to the first transfer line, a second mounting head that is adjacent to the second transfer line, and a first controller configured to control the first mounting head and the second mounting head of the first surface mounting equipment, the second surface mounting equipment includes a first mounting head that is adjacent to the first transfer line, a second mounting head that is adjacent to the second transfer line, and a second controller configured to control the first mounting head and the second mounting head of the second surface mounting equipment, the first controller is further configured to control the first surface mounting equipment so that the first surface mounting equipment performs an operation including continuous mounting, when the second surface mounting equipment stops working, the first controller is further configured to control the first surface mounting equipment to perform preceding mounting, in the continuous mounting, the first surface mounting equipment is configured to perform either separate mounting or collaborative mounting while giving priority to the separate mounting, the separate mounting is an operation in which each of the first mounting head and the second mounting head is configured to perform a main mounting operation on a main substrate, the collaborative mounting is an operation in which one of the first mounting head and the second mounting head is configured to perform a main mounting operation on a main substrate, while the other one of the first mounting head and the second mounting head is configured to simultaneously perform a sub-mounting operation on a sub-substrate, the preceding mounting is performed by the first mounting head of the first surface mounting equipment as a main mounting operation to which a main mounting operation of the first mounting head of the second surface mounting equipment is added, and the main mounting operation is an operation in which the first mounting head of the first surface mounting equipment or the first mounting head of the second surface mounting equipment is configured to perform an operation on a main substrate placed on the first transfer line or the second mounting head of the first surface mounting equipment or the second mounting head of the second surface mounting equipment is configured to perform an operation on a main substrate placed on the second transfer line, the sub-mounting operation is an operation in which the first mounting head of the first surface mounting equipment or the second mounting head of the second surface mounting equipment is configured to perform an operation on a sub-substrate placed on the second transfer line or the second mounting head of the first surface mounting equipment or the second mounting head of the second surface mounting equipment is configured to perform an operation on a sub-substrate placed on the first transfer line, the main substrate includes a substrate placed on the first transfer line with respect to the first mounting head or on the second transfer line with respect to the second mounting head, and the sub-substrate includes a substrate placed on the second transfer line with respect to the first mounting head or a substrate placed on the first transfer line with respect to the second mounting head.

### BRIEF DESCRIPTION OF THE DRAWINGS

Example embodiments of the inventive concepts will be more clearly understood from the following detailed description taken in conjunction with the accompanying drawings in which:

FIG. 1 is a conceptual diagram of component mounting equipment according to an example embodiment;

FIG. 2 illustrates component mounting equipment according to an example embodiment;

FIG. 3 illustrates component mounting equipment according to an example embodiment;

FIG. 4 illustrates component mounting equipment according to an example embodiment;

FIG. 5 illustrates component mounting equipment according to an example embodiment;

FIG. 6 is a conceptual diagram of component mounting equipment according to an example embodiment; and

FIGS. 7A to 7E are diagrams for explaining preceding of mounting process of component mounting equipment, according to an example embodiment.

### DETAILED DESCRIPTION

As used herein, expressions such as “one of” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, one or more example embodiments of the inventive concepts will be described in detail with reference to the attached drawings.

One or more example embodiments are provided so that this disclosure will fully convey the scope of example embodiments to one of ordinary skill in the art. The example embodiments below are embodied in many different forms and should not be construed as being limited to the example embodiments set forth herein. Rather, these example embodiments are provided so that this disclosure will be thorough and complete, and will fully convey the scope of example embodiments to one of ordinary skill in the art. In addition, sizes and thicknesses of layers in the drawings are exaggerated for clarity and convenience of explanation.

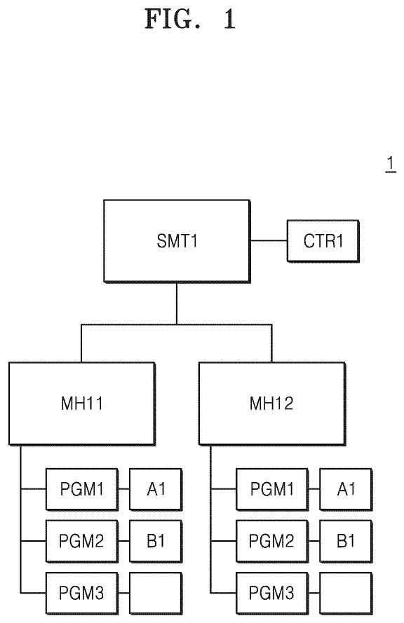

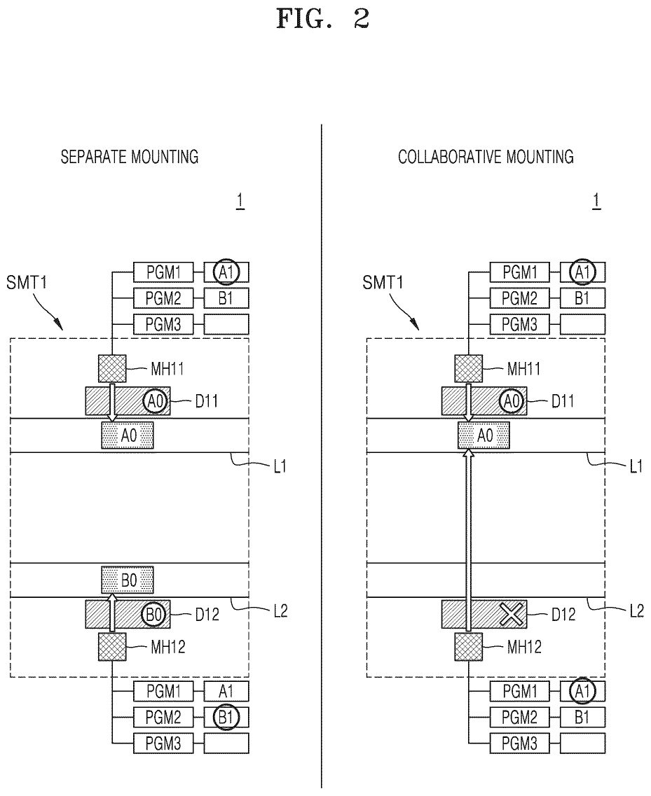

FIG. 1 is a conceptual diagram of component mounting equipment 1 according to an example embodiment. FIG. 2 illustrates the component mounting equipment 1 according to an example embodiment.

Referring to FIG. 1, first surface mounting equipment SMT1 may include a first mounting head MH11 and a second mounting head MH12. The first surface mounting equipment SMT1 may include a driver that manages operations, including an operation in which the first mounting head MH11 and the second mounting head MH12 pick up components to be mounted on a substrate and an operation in which the first mounting head MH11 and the second mounting head MH12 mount the components on the substrate. A first controller CTR1 may be included in the first surface mounting equipment SMT1. The first controller CTR1 may control overall operations and functions of the first surface mounting equipment SMT1.

The first mounting head MH11 and the second mounting head MH12 may each operate with three or more programs. For example, the first mounting head MH11 and the second mounting head MH12 may each operate with up to three programs. The first mounting head MH11 may operate based on a first program PGM1, a second program PGM2, and a third program PGM3. As shown in FIG. 1, the first program PGM1 may be an A1 program and the second program PGM2 may be a B1 program. The third program PGM3 may not include an operation program or may not be designated. The term ‘operation program’ refers to a program for performing a component mounting operation on a substrate.

The program may be stored in a controller of the surface mounting equipment. For example, the first program PGM1, the second program PGM2, and the third program PGM3 of the first mounting head MH11 may be stored in the first controller CTR1. Such descriptions may also be applied to the second mounting head MH12 and a second controller CTR2 of second surface mounting equipment SMT2 and a third controller CTR3 of third surface mounting equipment SMT3 described below.

The program enables a mounting head to perform a component mounting operation on a targeted substrate. Through the program, the mounting head may perform the component mounting operation by arranging a specific component at a designated location of the substrate. When mounting components on different substrates, the mounting head may use different programs.

Also, even if substrates with the same final result are targeted by the mounting head, the programs applied to the mounting head may be different when the stages of the component mounting operation are different. For example, on the substrate requiring ten component mounting operations, the program for the third component mounting operation may be different from that for the fourth component mounting operation.

In addition, even if substrates with the same final result are targeted for the component mounting, the program applied to the mounting head may vary depending on whether the target is the front surface of the substrate or the rear surface thereof which is opposite to the front surface. In summary, when different programs are applied to the mounting head, the mounting head performs different operations. In addition, depending on the program applied to the mounting head, the operations performed by the mounting head vary.

Referring to FIG. 2, the component mounting equipment 1 may perform separate mounting and collaborative mounting. The term ‘separate mounting’ refers to the process where mounting heads independently perform the component mounting operations. That is, the first mounting head MH11 and the second mounting head MH12 of the first surface mounting equipment SMT1 perform the mounting operations, respectively, on the substrate. The collaborative mounting is described below.

During the separate mounting, for example, as shown in FIG. 2, the first mounting head MH11 may perform the component mounting operation on an A0 substrate by using the A1 program. In the present specification, for example, the A0 substrate may be changed to an A1 substrate after the component mounting operation, and the program executed by the mounting head to achieve such change may be the A1 program. That is, the A0 substrate may be converted into an A1 substrate through a component mounting process using the A1 program.

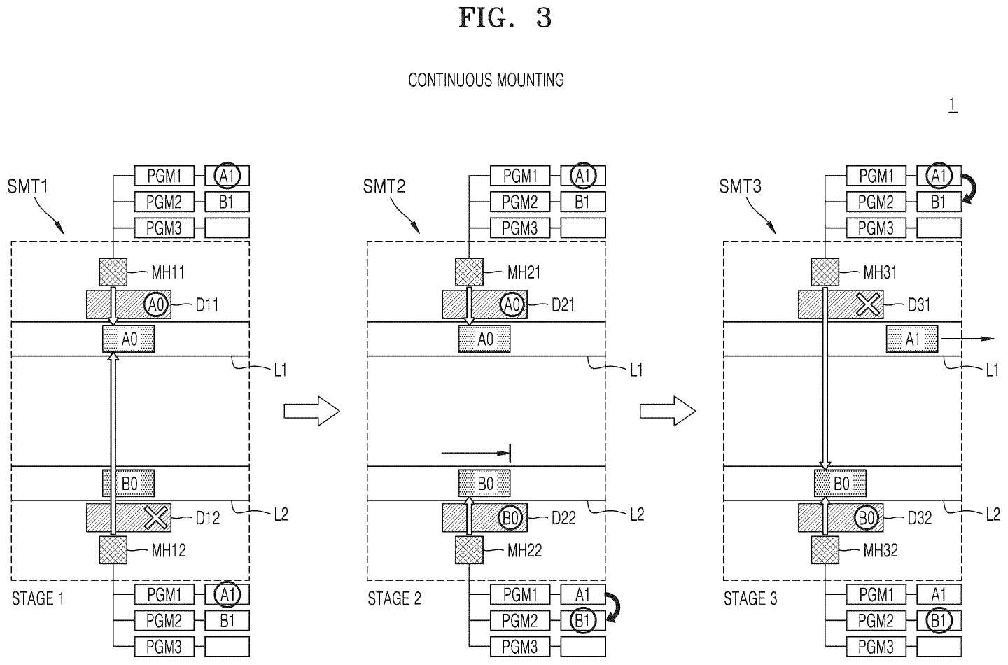

As described above, each mounting head may be equipped with three or more programs. For example, the first mounting head MH11 and the second mounting head MH12 may each be equipped with up to three programs. As shown in FIG. 3, for example, the first mounting head MH11 may be equipped with up to three programs, and two programs (e.g., the A1 program and the B1 program) may be loaded onto the first mounting head MH11. In addition, the second mounting head MH12 may be equipped with up to three programs, and two programs (e.g., the A1 program and the B1 program) may be loaded onto the second mounting head MH12. In other words, because each of the first mounting head MH11 and the second mounting head MH12 are equipped with the A1 program and the B1 program, the first mounting head MH11 and the second mounting head MH12 may perform the component mounting operations on the A0 substrate and the B0 substrate, respectively.

The first surface mounting equipment SMT1 may include substrate sensors corresponding to the first mounting head MH11 and the second mounting head MH12, respectively. The substrate sensors may identify whether the substrates are positioned at the locations where the first mounting head MH11 and the second mounting head MH12 perform the component mounting operations and also identify the types of substrates.

The shapes and positions of a first substrate sensor D11 and a second substrate sensor D12 are shown in FIG. 2 for understanding. The O or X marks on the first substrate sensor D11 and the second substrate sensor D12 of FIG. 2 are simplified indications showing whether a substrate has reached each substrate sensor. In addition, marks, such as A0 or B0, inside the O marks on the first substrate sensor D11 and the second substrate sensor D12 of FIG. 2 clearly denote the types of substrates identified by the first and second substrate sensors D11 and D12.

For example, as shown in FIG. 2, when the substrate has reached a work area of the first mounting head MH11 where the first mounting head MH11 may operate, the first substrate sensor D11 for sensing the substrate having reached the work area of the first mounting head MH11 may be included in the first surface mounting equipment SMT1. In other words, the first substrate sensor D11 may detect that the substrate has reached the work area of the first mounting head MH11 and identify that the substrate is the A0 substrate. The first substrate sensor D11 may transmit information to the first controller CTR1 of the first surface mounting equipment SMT1 shown in FIG. 1, wherein the information indicates that the substrate having reached the work area of the first mounting head MH11 is the A0 substrate. The substrate sensor may recognize a recognition unit marked on each substrate and identify the substrate. The recognition unit marked on each substrate may include, for example, a QR code or barcode.

In the present specification, the work area of the first mounting head MH11 refers to the location on the substrate, where the component mounting operation may be carried out, in a first transfer line L1 that is relatively close to the first mounting head MH11. In addition, a work area of the second mounting head MH12 refers to the location on the substrate, where the component mounting operation may be carried out, in a second transfer line L2 that is relatively close to the second mounting head MH12.

The first substrate sensor D11 may transmit the information, which indicates that the substrate having reached the first work area is the A0 substrate to at least one or all of the first controller CTR1 of the first surface mounting equipment SMT1 and an integrated controller for collectively controlling multiple component mounting devices. The information of the substrate identified through the first substrate sensor D11 may record and track the progress of operations performed on the substrate in at least one of the aforementioned controllers.

The first mounting head MH11 of the first surface mounting equipment SMT1 may mount components on the A0 substrate, which has reached the first work area, by using the A1 program selected from among the A1 program and the B1 program.

Substrates in the work areas close to the first mounting head MH11 and the second mounting head MH12 may be referred to as main substrates, while substrates in distant work areas may be referred to as sub-substrates. For example, as shown in FIG. 2, the A0 substrate that is relatively close to the first mounting head MH11 may be the main substrate of the first mounting head MH11, and the B0 substrate that is relatively far from the first mounting head MH11 may be the sub-substrate of the first mounting head MH11. On the other hand, the B0 substrate that is close to the second mounting head MH12 may be the main substrate of the second mounting head MH12, and the A0 substrate that is relatively distant from the second mounting head MH12 may be the sub-substrate of the second mounting head MH12. That is, separate mounting involves performing component mounting on the main substrate of the first mounting head MH11 and subsequently on the main substrate of the second mounting head MH12.

Additionally, in the present specification, a main mounting program is defined as a program used for operations on the main substrate by the mounting head. For example, in the separate mounting shown in FIG. 2, because the program for processing the A0 substrate, which is the main substrate of the first mounting head MH11, is the A1 program, the A1 program is the main mounting program of the first mounting head MH11. Because the program for processing the B0 substrate, which is the main substrate of the second mounting head MH12, is the B1 program, the B1 program is the main mounting program of the second mounting head MH12.

Additionally, the term ‘main mounting operation’ used in the present specification denotes that a mounting head performs a component mounting operation on a main substrate. For example, in the separate mounting shown in FIG. 2, the main substrate of the first mounting head MH11 is the A0 substrate, and the process in which the first mounting head MH11 performs the component mounting operation on the A0 substrate using the A1 program may be referred to as the main mounting operation.

Therefore, separate mounting refers to the process where each of the two mounting heads performs its own main mounting operation. When such a definition is applied to the separate mounting of FIG. 2, the main mounting operation is performed on the A0 substrate, which is the main substrate of the first mounting head MH11, by using the A1 program that is the main mounting program of the first mounting head MH11, and the main mounting operation is performed on the B0 substrate, which is the main substrate of the second mounting head MH12, by using the B1 program that is the main mounting program of the second mounting head MH12.

As shown in FIG. 2, when the substrate has reached a work area of the second mounting head MH12 where the second mounting head MH12 may operate, the second substrate sensor D12 for sensing the arrival of the substrate to the work area of the second mounting head MH12 may be included in the first surface mounting equipment SMT1. The second substrate sensor D12 may identify that the substrate having reached the work area of the second mounting head MH12 is the B0 substrate. The second mounting head MH12 of the first surface mounting equipment SMT1 may mount the components on the B0 substrate, which has reached the work area of the second mounting head MH12, by using the B1 program selected from among the A1 program and the B1 program.

The component mounting equipment 1 according to an example embodiment may perform collaborative mounting. Collaborative mounting refers to the process where, when the substrate that is the work target is located only in one of the work area of the first mounting head MH11 and the work area of the second mounting head MH12, both the first mounting head MH11 and the second mounting head MH12 work together to mount components on the targeted substrate. As shown in FIG. 2, for example, when the first substrate sensor D11 detects that the A0 substrate is in the first work area and the second substrate sensor D12 finds no substrate in the second work area, the first mounting head MH11 and the second mounting head MH12 may simultaneously mount components on the A0 substrate having reached the first work area.

The A0 substrate may reach the work area of the first mounting head MH11 and be positioned therein through the first transfer line L1 that is adjacent to the first mounting head MH11. In this case, the first mounting head MH11 and the second mounting head MH12 may respectively perform component mounting on the A0 substrate by using the A1 program. However, the moving distance of the first mounting head MH11 during component loading and mounting is less than the moving distance of the second mounting head MH12 during component loading and mounting. Therefore, the travel time of the first mounting head MH11 during component loading and mounting is less than that of the second mounting head MH12 during component loading and mounting.

In the present specification, a sub-mounting program refers to a program used by the mounting head to process the sub-substrate. For example, in the collaborative mounting of FIG. 2, because the program for processing the B0 substrate, which is the sub-substrate of the first mounting head MH11, is the B1 program, the B1 program is the sub-mounting program of the first mounting head MH11. Because the program for processing the A0 substrate, which is the sub-substrate of the second mounting head MH12, is the A1 program, the A1 program is the sub-mounting program of the second mounting head MH12.

Additionally, the term ‘sub-mounting operation’ used in the present specification denotes that a mounting head performs a component mounting operation on a sub-substrate. For example, in the collaborative mounting of FIG. 2, the sub-substrate of the first mounting head MH11 is the B0 substrate, and the process performing, by the first mounting head MH11, the component mounting operation on the B0 substrate by using the B1 program may be referred to as the sub-mounting operation.

Therefore, collaborative mounting refers to the process where two mounting heads simultaneously performs the main mounting operation and the sub-mounting operation, respectively. In addition, the mounting head for performing the main mounting operation performs an operation by using the main mounting program, and the mounting head for performing the sub-mounting operation performs an operation by using the sub-mounting program.

When such a definition is applied to the collaborative mounting of FIG. 2, the first mounting head MH11 performs the operation on the A0 substrate, which is the main substrate of the first mounting head MH11, by using the A1 program that is the main mounting program of the first mounting head MH11, and the second mounting head MH12 performs the operation on the A0 substrate, which is the sub-substrate of the second mounting head MH12, by using the A1 program that is the sub-mounting program of the second mounting head MH12.

In the present specification, the term ‘main mounting head’ refers to a mounting head performing a main mounting operation, and the term ‘sub-mounting head’ denotes a mounting head performing a sub-mounting operation.

FIG. 3 illustrates the component mounting equipment 1 according to an example embodiment.

Referring to FIG. 3, the component mounting equipment 1 according to an example embodiment may perform continuous mounting. Continuous mounting refers to the process where two mounting heads selectively perform the separate mounting and the collaborative mounting, while prioritizing separate mounting over collaborative mounting. Therefore, while two mounting heads are engaged in the collaborative mounting, one of the two mounting heads may discontinue collaborative mounting and switch to perform separate mounting.

In other words, each of the two mounting heads may selectively perform the main mounting operation and the sub-mounting operation while giving priority to the main mounting operation over the sub-mounting operation. While two mounting heads are carrying out the main mounting operation and the sub-mounting operation, when the sub-mounting head is able to perform the main mounting operation, that is, when the main substrate of the sub-mounting head has reached the work area of the sub-mounting head, the sub-mounting head may pause the sub-mounting operation and start the main mounting operation.

For example, as in stage 1, each of the first mounting head MH11 and the second mounting head MH12 may use the A1 program to perform component mounting on the A0 substrate located in the work area of the first mounting head MH11. As in stage 2, a substrate that needs to be processed may reach the work area of the second mounting head MH12 through the second transfer line L2. The second substrate sensor D12 may identify the arrived substrate and detect that the B0 substrate has reached the work area of the second mounting head MH12.

According to a signal from the second substrate sensor D12, the second mounting head MH12, which is currently processing the A0 substrate in the work area of the first mounting head MH11, may stop the operation on the A0 substrate and move to the work area of the second mounting head MH12 to begin the operation on the B0 substrate. That is, the second mounting head MH12 may stop the ongoing collaborative mounting and perform separate mounting on the B0 substrate that is in the work area of the second mounting head MH12 that is relatively close to the second mounting head MH12.

However, in stage 1, the second mounting head MH12 may perform the operation on the A0 substrate by using the A1 program that is the first program PGM1. In stage 2, the second mounting head MH12 may switch to the B1 program, which is the second program PGM2, to perform the operation on the B0 substrate located in the work area of the second mounting head MH12. The program transition from the A1 program to the B1 program in the second mounting head MH12 is visually illustrated by an arrow.

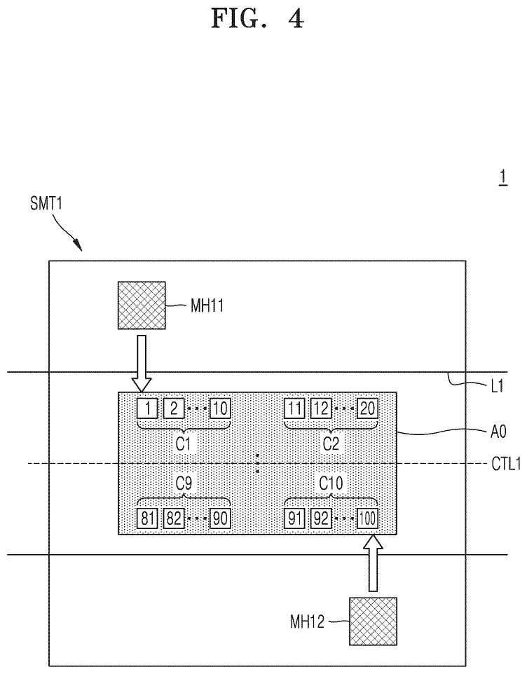

However, because the sub-mounting head interrupts the operation on the sub-substrate and moves to perform the main mounting operation, the sub-mounting operation is left incomplete and is discontinued. This is described below with reference to FIG. 4.

As in stage 3 shown in FIG. 3, following the completion of the collaborative mounting operation on the A0 substrate by the first mounting head MH11 and the second mounting head M12 in stage 1, the A0 substrate may be transferred to the next work area as an A1 substrate via the first transfer line L1. The operation on the A0 substrate in the work area of the first mounting head MH11 may be completed more quickly than that on the B0 substrate in the work area of the second mounting head MH12 because of collaborative mounting and separate mounting. That is, because the operation on the A0 substrate adjacent to the first mounting head MH11 is finished earlier, the first mounting head MH11 may carry out collaborative mounting on the B0 substrate, on which the component mounting operation starts later than on the A0 substrate.

In stage 2, however, the first mounting head MH11 performs the operation on the A0 substrate by using the A1 program that is the first program PGM1. After completing the component mounting operation on the A0 substrate, the first mounting head MH11 may switch to the B1 program, which is the second program PGM2, in stage 3 to perform the operation on the B0 substrate, which is handled by the second mounting head MH12. The program transition from the A1 program to the B1 program in the first mounting head MH11 is visually illustrated by an arrow.

In stage 3, because the second mounting head MH12 is already performing the component mounting operation on the B0 substrate, the stages of the operation using the B1 program may be transmitted to the first mounting head MH11 to prevent overlapping of tasks or conflicts between the second mounting head MH12 and the first mounting head MH11. The stages of the component mounting operation by the second mounting head MH12 using the B1 program may be identified in units of cycles, and the detailed method for such identification is provided below with reference to FIG. 4.

Continuous mounting involves a process where, initially, when one substrate is located inside the first surface mounting equipment SMT1, two mounting heads perform a main mounting operation and a sub-mounting operation, respectively, on the substrate, when an additional substrate is transferred into the first surface mounting equipment SMT1, the mounting heads respectively perform a main mounting operation on the two substrates, and subsequently, when the component mounting operation on one substrate is completed leaving the other, the mounting heads perform the main mounting operation and the sub-mounting operation, respectively, on the remaining substrate.

By performing continuous mounting in the component mounting equipment 1, it may be possible to reduce the period during which the mounting heads in the component mounting equipment 1 do not execute the component mounting operations. Therefore, the component mounting equipment 1 according to an example embodiment may have improved productivity of component mounting operation.

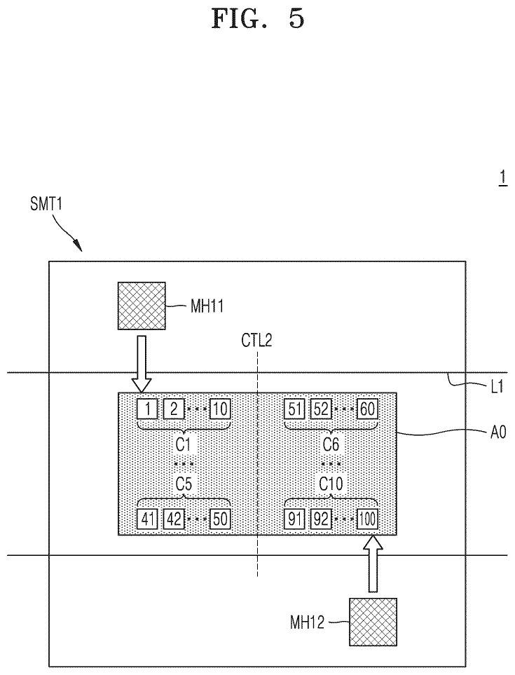

FIG. 4 illustrates the component mounting equipment 1 according to an example embodiment. FIG. 5 illustrates the component mounting equipment 1 according to an example embodiment.

Referring to FIGS. 3 and 4 together, two mounting heads of the component mounting equipment are able to perform continuous mounting as described above. During continuous mounting, the methods of component mounting by the two mounting heads are altered. For example, when a sub-substrate is transferred through a transfer line during collaborative mounting, the mounting head previously performing the sub-mounting operation halts the sub-mounting operation and switches to the main mounting operation. On the other hand, in separate mounting in which each mounting head performs the main mounting operation, when any one of the mounting heads finishes its operation early, the one of the mounting heads performs the sub-mounting operation on another substrate that still undergoes the main mounting operation.

During collaborative mounting, when any one of the mounting heads switches to separate mounting, the sub-mounting head halts the ongoing sub-mounting operation to perform the main mounting operation, and thus, the sub-mounting operation by the sub-mounting head may be discontinued.

In addition, when separate mounting by individual mounting heads is changed to collaborative mounting for a single substrate, while one mounting head performs the main mounting operation, another mounting head having performed the main mounting operation may join and perform the sub-mounting operation midway, ensuring that the sub-mounting operation and the main mounting operation are concurrently executed on the same substrate.

To facilitate continuous mounting, as shown in FIG. 4, components to be mounted on the substrate may be organized into multiple cycles, allowing for the tracking and management of the component mounting operations. The sub-mounting operations during collaborative mounting may be discontinued in cycle units instead of component units, and the sub-mounting operations during separate mounting may be initiated in cycle units rather than component units.

The component mounting operation performed in cycle units is illustratively described with reference to FIG. 4. As shown in FIG. 4, the first mounting head MH11 of the surface mounting equipment SMT1 may perform the main mounting operation on the A0 substrate that is the main substrate. The second mounting head MH12 may perform the sub-mounting operation on the A0 substrate that is the sub-substrate. FIG. 4 is an enlarged view of the collaborative mounting operation in stage 1 of continuous mounting shown in FIG. 3, centered around the substrate.

For example, the number of components that should be loaded during the component mounting operation performed on the A0 substrate by using the A1 program may be 100. The mounting head may organize 100 components into multiple cycles and mount the same. For example, the 100 components that should be mounted on the A0 substrate may be grouped into ten cycles from a first cycle C1 to a tenth cycle C10, wherein each cycle includes ten components. That is, the A1 program may be the program enabling the component mounting operation to be performed on the A0 substrate in the first cycle C1 to the tenth cycle C10.

Components 1 to 10 are grouped into the first cycle C1, components 11 to 20 are grouped into the second cycle C2, and similarly, each of the cycles from the third cycle C3 to the tenth cycle C10 may include ten components. The components may include components mounted on a substrate, for example, passive elements, semiconductor chips, diodes, transistors, and lines.

Based on the ten cycles described above, the component mounting operation may start or stop. In the process where collaborative mounting switches to separate mounting by individual mounting heads, the sub-mounting operation by the sub-mounting head may stop. Using FIG. 4 as an example, the component mounting operation may be performed on the A0 substrate, with the first mounting head MH11 serving as the main mounting head and the second mounting head MH12 as the sub-mounting head. The first mounting head MH11 mounts components 1 to 10, which are included in the first cycle C1, and proceeds to mount components 11 to 20, which are included in the second cycle C2, after completing the component mounting in the first cycle C1. In the aforementioned order, the operations may be performed in cycle units.

When two mounting heads simultaneously perform the component mounting operations on the substrate, one of the two mounting heads may carry out the main mounting operation for the earlier-numbered cycles among multiple cycles. The other mounting head, on the other hand, may perform the sub-mounting operation for the later-numbered cycles among the multiple cycles. Such a case corresponds to the collaborative mounting.

The component mounting operations are tracked in cycle units, and when the sub-mounting head disengages during collaborative mounting, any cycles completed by the sub-mounting head are tracked and transmitted to the main mounting head. Moreover, the component mounting operations are tracked in cycle units, and when separate mounting switches to collaborative mounting and the sub-mounting head joins, any cycles completed by the sub-mounting head may be tracked and transmitted to the main mounting head.

In a component tray, a series of processes, including picking up components by the mounting head, moving the mounting head picking up the components, performing component mounting by the mounting head, and transferring the mounting head to its original position on the component tray, may be the above-described component mounting operation in cycle units. In other words, a series of processes including picking up the components by the mounting head and returning the mounting head to its original position in the component tray may be a mounting operation in one cycle. Therefore, when ten components are picked up and mounted during the process where the mounting picks up the component and returns to its original position on the component tray, the number of components in one cycle may be ten. In this case, when 100 components are to be mounted on a single substrate, the component mounting operation for the substrate may include ten cycles each including ten components.

Because the component mounting operations by the mounting heads are fast-paced, tracking the component mounting operations in component units may be challenging. Even when the component mounting operations are tracked in component units, switching between separate mounting and collaborative mounting in component units may not be easy.

By managing component mounting operations in cycle units, the progress of such component mounting operations during separate mounting, collaborative mounting, and continuous mounting may be smoothly tracked on a cycle basis, thereby reducing idle time for two mounting heads. Therefore, through the component mounting equipment 1 for tracking component mounting operations in cycle units, the component mounting operations may be more efficiently executed. Additionally, when cycles are distinguished based on the positions of components, interference between the main mounting head and the sub-mounting head during collaborative mounting may decrease.

When the sub-mounting head is separated from the sub-substrate during the sub-mounting operation, the number of completed cycles may be transmitted to the controller of the surface mounting equipment. Based on the information received, the main mounting head may perform the main mounting operation. Therefore, the main mounting head may not perform the main mounting operations for all of the cycles; instead, under the control of the controller, the main mounting head may perform the main mounting operations for the cycles excluding the cycles for which the sub-mounting head performs the sub-mounting operations. In other words, the tracking of cycles by the main mounting device or the sub-mounting device may be executed by the controller of the surface mounting equipment.

In collaborative mounting shown in FIG. 4, the second mounting head MH12 may perform the sub-mounting operation simultaneously with the initiation of the component mounting operation by the first mounting head MH11. For example, while the first mounting head MH11 performs the component mounting operation for the components in the first cycle C1, the second mounting head MH12 may simultaneously perform the component mounting operation for the components in the tenth cycle C10. In this case, the first mounting head MH11 and the second mounting head MH12 perform the component mounting operations for a similar number of cycles (e.g., five cycles), respectively, and thus, the first mounting head MH11 and the second mounting head MH12 may complete the component mounting operations on the substrate at approximately similar points in time.

In some example embodiments, the second mounting head MH12 may join the component mounting operation by the first mounting head MH11 midway to start the sub-mounting operation. For example, after the first mounting head MH11 performs the component mounting operation for the components in the first cycle C1 to the second cycle C2, the second mounting head MH12 may start the component mounting operation for the components in the tenth cycle C10.

The main mounting head performing the main mounting operation may carry out sequential mounting in cycle units, and the sub-mounting head performing the sub-mounting operation may perform reverse mounting in cycle units, wherein the mounting operations for the earlier-numbered cycles are performed during sequential mounting, and the mounting operations for the later-numbered cycles are performed during reverse mounting. As described above, the first mounting head MH11 performing the main mounting operation may perform sequential mounting from the first cycle C1 to the second cycle C2, while the second mounting head MH12 performing the sub-mounting operation may perform reverse mounting from the tenth cycle C10 to the ninth cycle C9.

While the second mounting head MH12 performs the mounting operation for the tenth cycle C10, components 91 to 100 in the tenth cycle C10 may be mounted in an ascending order from component 91 to component 100 or a descending order from component 100 to component 91. The order may be determined based on the configurations of the component mounting equipment, the arrangements of the components on the substrates, and the selection made by an operator.

When separate mounting by individual mounting heads is changed to collaborative mounting for a single substrate, the sub-mounting head performs the sub-mounting operation midway during separate mounting, and thus, the sub-mounting operation by the sub-mounting head begins simultaneously with the main mounting operation.

For example, after the first mounting head MH11 that is the main mounting head mounts the component up to the second cycle C2, the second mounting head MH12 that is the sub-mounting head may join the operation to perform collaborative mounting. The first controller CTR1 may control the second mounting head MH12 to start the sub-mounting operation from the tenth cycle C10 and continue to perform the sub-mounting operation to the seventh cycle C7. Moreover, because the second mounting head MH12 has joined the sub-mounting operation after the first mounting head MH11 completed the main mounting operation up to the second cycle C2, the first mounting head MH11 may be controlled by the first controller CTR1 to continue the main mounting operation only up to the sixth cycle C6 instead of up to the tenth cycle C10.

After the start of collaborative mounting, the first mounting head MH11 performs the main mounting operations for the third cycle C3 to the sixth cycle C6, while the second mounting head MH12 carries out sub-mounting operations for the seventh cycle C7 to the tenth cycle C10. That is, after collaborative mounting starts, each of the first mounting head MH11 and the second mounting head MH12 performs mounting operations for four cycles. Therefore, the collaborative mounting by the first mounting head MH11 and the second mounting head MH12 may be terminated at approximately the same points in time.

The specific settings for how far the sub-mounting head operating in conjunction with the main mounting head should perform component mounting are determined by considering, for example, user or task characteristics, the shape of the substrate, and the features of the mounting equipment.

For example, as illustrated in FIG. 4, the method of grouping components into the cycles may include categorizing the components based on a first virtual central line CTL1 extending in the same direction as the first transfer line L1 and grouping components relatively close to the first mounting head MH11, which is the main mounting head, into the first cycle C1 to the fifth cycle which are earlier-numbered cycles. Additionally, by categorizing the components based on the first virtual central line CTL1, components relatively close to the second mounting head MH12, which is the sub-mounting head, may be grouped into the sixth cycle to the tenth cycle C10 which are later-numbered cycles.

By arranging the later-numbered cycles to be relatively close to the second mounting head MH12, which is the sub-mounting head and starts the operation from the tenth cycle C10, the travel distance of the second mounting head MH12 performing component mounting in a reverse order may be reduced. Moreover, interference between two mounting heads may be reduced or prevented by dividing the cycles and performing the component mounting operations.

In some example embodiments, to facilitate the component mounting operations, multiple cycles may be generated by dividing them based on the component locations on the substrate, the main mounting head may start mounting operations from the cycle that is relatively close to the main mounting head among the cycles, and the sub-mounting head may also start mounting operations from the cycle that is relatively close to the sub-mounting head among the cycles. On the substrate, components relatively close to the main mounting head may be grouped into earlier-numbered cycles, and those relatively close to the sub-mounting head may be grouped into later-numbered cycles, thus generating multiple cycles.

For example, as illustrated in FIG. 4, on the A0 substrate, components 1 to 10 near the first mounting head MH11, which is the main mounting head, may be grouped into the first cycle C1, and components 11 to 20 that are next closest to the first mounting head MH11 may be grouped into the second cycle C2. Similarly, on the A0 substrate, components 91 to 100 near the second mounting head MH12, which is the sub-mounting head, may be grouped into the tenth cycle C10, and components 81 to 90 that are next closest to the second mounting head MH12 may be grouped into the ninth cycle C9.

On the A0 substrate, the first mounting head MH11, which is the main mounting head, may start the component mounting operation from the first cycle C1 which is relatively close to the first mounting head MH11. In addition, on the A0 substrate, the second mounting head MH12, which is the sub-mounting head, may start the component mounting operation from the tenth cycle C10 which is relatively close to the second mounting head MH12.

Referring to FIGS. 3 and 5 together, unlike in FIG. 4, the method of grouping the components into the cycles may include, for example, dividing the components based on a second virtual central line CTL2 crossing the center of the substrate and extending perpendicular to the first transfer line L1. Based on the second virtual central line CTL2, the components arranged at the rear of the A0 substrate may be grouped into the first cycle C1 to the fifth cycle C5 which are earlier-numbered cycles among the ten cycles. In addition, by categorizing the components based on the second virtual central line CTL2, the components on the front of the A0 substrate may be grouped into the sixth cycle C6 to the tenth cycle C10 which are later-numbered cycles among the ten cycles.

In the present specification the front of the substrate refers to a portion of the substrate that faces the direction towards which the mounting operation processes and the substrate is transferred, while the rear of the substrate denotes a portion facing the direction from which the substrate is transferred. That is, in FIG. 5, based on the second virtual central line CTL2, the left side may be the rear of the substrate, and the right side may be the front of the substrate.

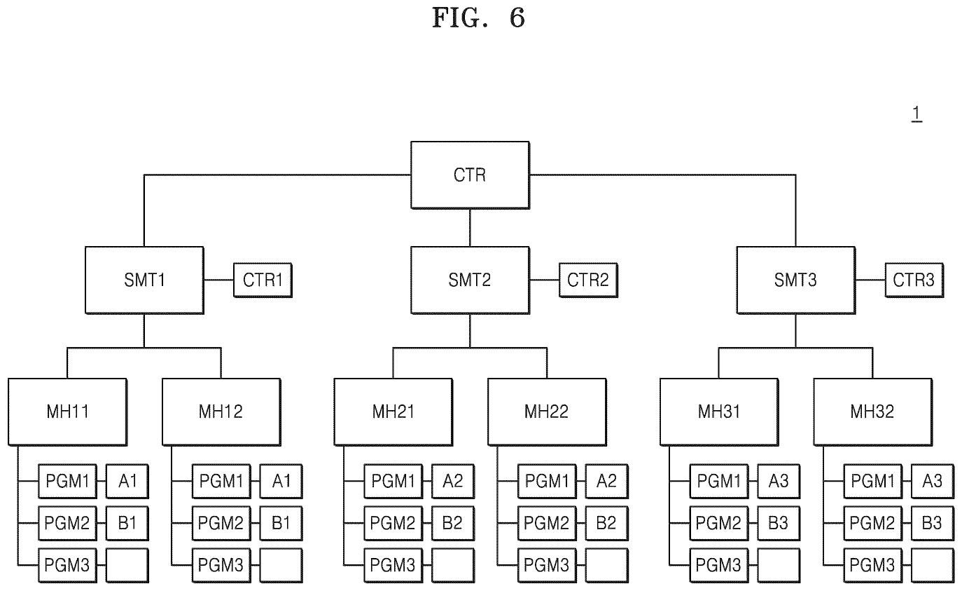

FIG. 6 is a conceptual diagram of the component mounting equipment 1 according to an example embodiment.

Referring to FIG. 6, the first surface mounting equipment SMT1 may include the first mounting head MH11 and the second mounting head MH12. The first surface mounting equipment SMT1 may include a driver (not shown) that manages operations, including an operation in which the first mounting head MH11 and the second mounting head MH12 pick up components to be mounted on a substrate and an operation in which the first mounting head MH11 and the second mounting head MH12 mount the components on the substrate.

The first mounting head MH11 and the second mounting head MH12 may each operate through three or more programs. For example, the first mounting head MH11 and the second mounting head MH12 may each operate through at most three programs. As shown in FIG. 6, the first program PGM1 may be an A1 program and the second program PGM2 may be a B1 program. The third program PGM3 may not be stored or designated.

Similar to the first surface mounting equipment SMT1, the second surface mounting equipment SMT2 may include a driver (not shown) that manages operations, including an operation in which a first mounting head MH21 and a second mounting head MH22 pick up components to be mounted on a substrate and an operation in which the first mounting head MH21 and the second mounting head MH22 mount the components on the substrate. A second controller CTR2 may be included in the second surface mounting equipment SMT2. The second controller CTR2 may control overall operations and functions of the second surface mounting equipment SMT2.

The first mounting head MH21 and the second mounting head MH22 may each operate through three or more programs. As shown in FIG. 6, the first program PGM1 may be an A2 program and the second program PGM2 may be a B2 program. The third program PGM3 may not be stored or designated.

Similar to the first surface mounting equipment SMT1, the third surface mounting equipment SMT3 may include a driver (not shown) that manages operations, including an operation in which a first mounting head MH31 and a second mounting head MH32 pick up components to be mounted on a substrate and an operation in which the first mounting head MH31 and the second mounting head MH32 mount the components on the substrate. A third controller CTR3 may control overall operations and functions of the third surface mounting equipment SMT3.

The first mounting head MH31 and the second mounting head MH32 may each operate through three or more programs. As shown in FIG. 6, the first program PCM1 may be an A3 program and the second program PGM2 may be a B3 program. The third program PGM3 may not be stored or designated.

Each program may include the mounting process desired for the mounting head to mount the components on the substrate targeted. Therefore, when different programs are applied to the mounting head, the mounting head conducts different tasks. In addition, depending on the program applied to the mounting head, the task performed by the mounting head differs.

As shown in FIG. 6, an integrated controller CTR may be included to collectively control the first surface mounting equipment SMT1, the second surface mounting equipment SMT2, and the third surface mounting equipment SMT3. The first surface mounting equipment SMT1, the second surface mounting equipment SMT2, and the third surface mounting equipment SMT3 may include the first controller CTR1, the second controller CTR2, and the third controller CTR3, respectively.

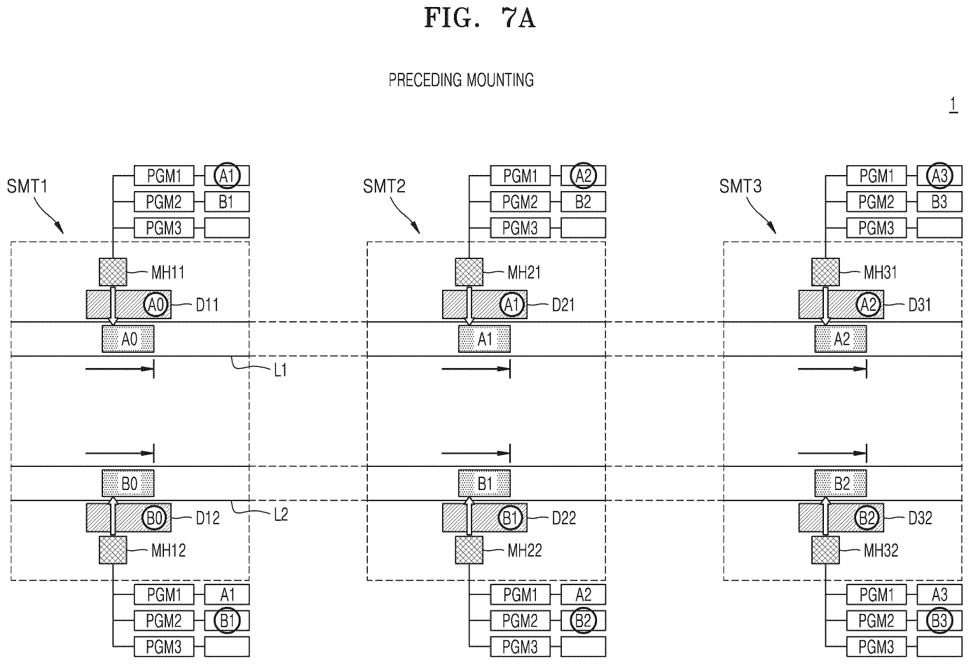

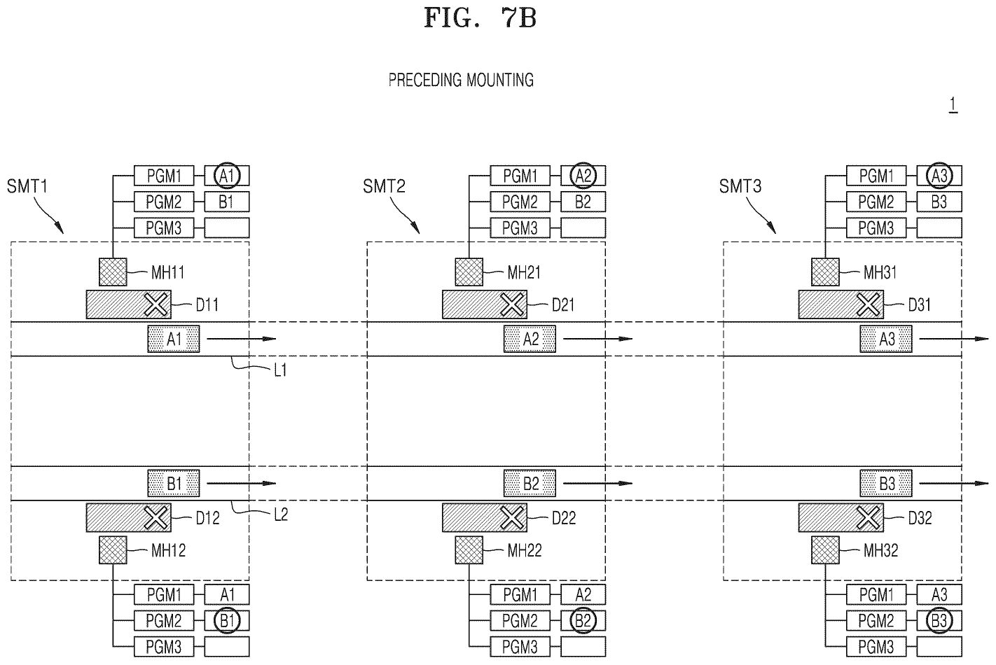

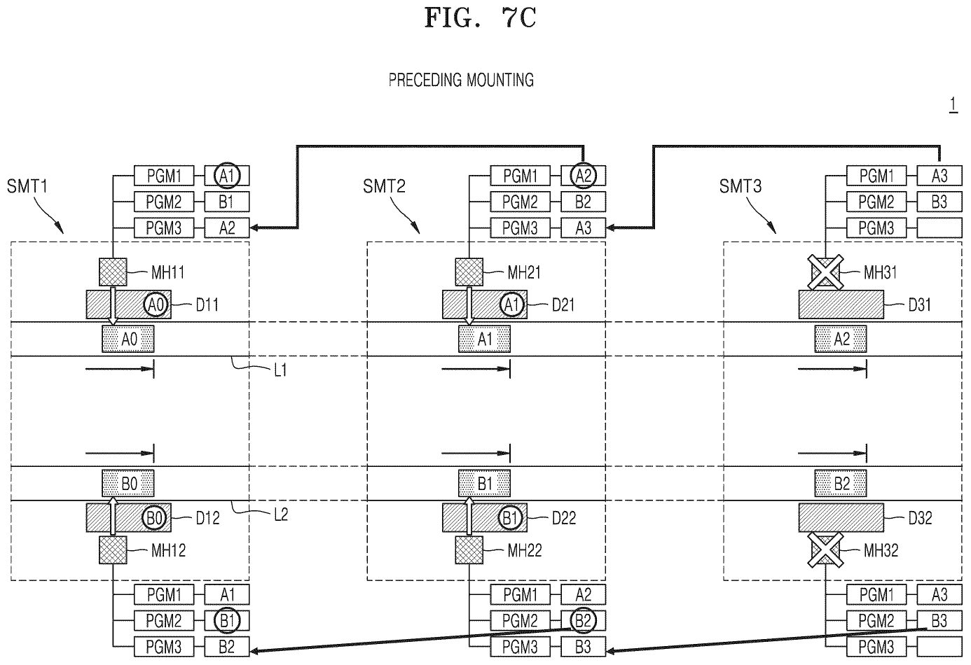

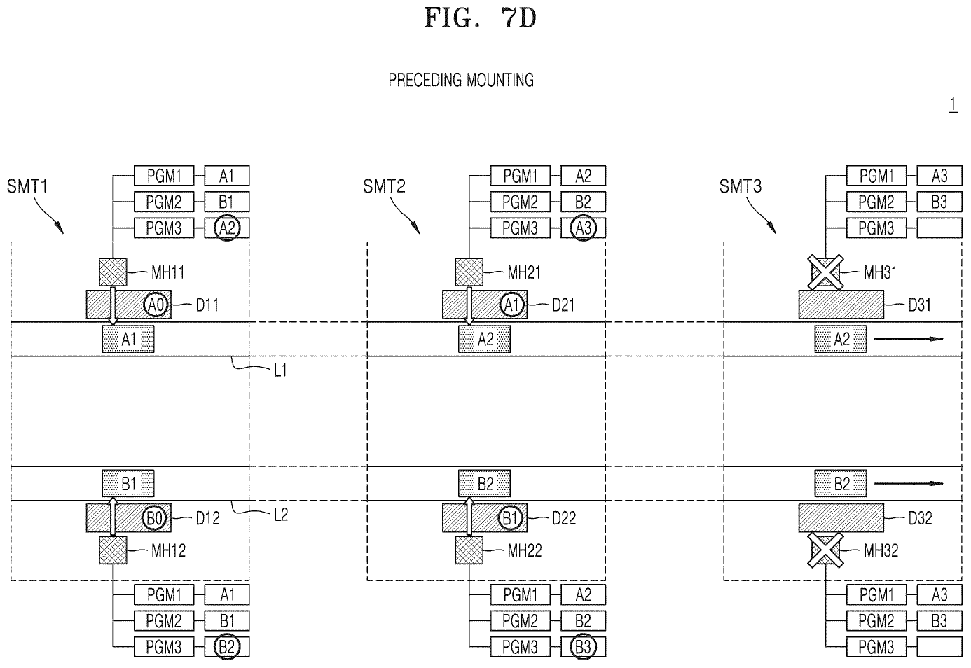

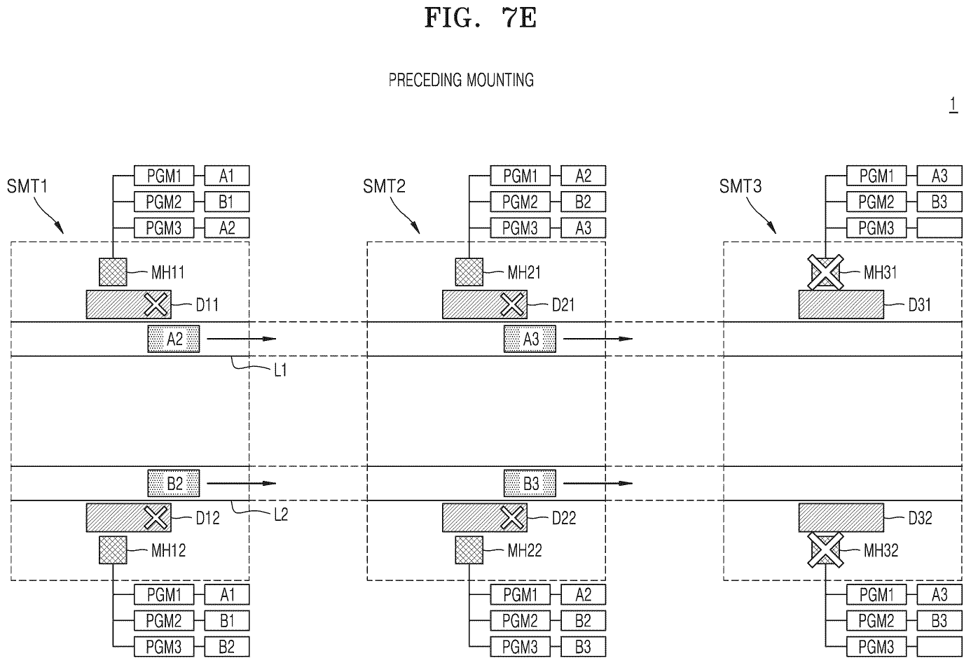

FIGS. 7A to 7E are diagrams for explaining preceding of mounting process of the component mounting equipment 1, according to an example embodiment.

Referring to FIGS. 7A and 7B, the first mounting head MH11 and the second mounting head MH12 of the first surface mounting equipment SMT1, the first mounting head MH21 and the second mounting head MH22 of the second surface mounting equipment SMT2, and the first mounting head MH31 and the second mounting head MH32 of the third surface mounting equipment SMT3 may perform the main mounting operations, respectively.

The substrates that are subject to the main mounting operation by the first mounting head MH11 and the second mounting head MH12 are the A0 substrate and the B0 substrate, respectively. The substrates that are subject to the main mounting operation by the first mounting head MH21 and the second mounting head MH22 are the A1 substrate and the B1 substrate, respectively. The substrates that are subject to the main mounting operation by the first mounting head MH31 and the second mounting head MH32 are the A2 substrate and the B2 substrate, respectively. When the main mounting operation has been completed on each substrate, the substrate may then move to the next mounting equipment through the first transfer line L1 and the second transfer line L2.

For example, after the main mounting operation using the A1 program by the first mounting head MH11 of the first surface mounting equipment SMT1 is completed on the A0 substrate and the A0 substrate is converted into the A1 substrate, the A1 substrate may be moved to the next work station in front of the first mounting head MH21 of the second surface mounting equipment SMT2 via the first transfer line L1.

After the main mounting operation using the A2 program by the first mounting head MH21 of the second surface mounting equipment SMT2 is completed on the A1 substrate and the A1 substrate is converted into the A2 substrate, the A2 substrate may be moved to the next work station in front of the first mounting head MH31 of the third surface mounting equipment SMT3 via the first transfer line L1. Similarly, after the main mounting operation using the A3 program by the first mounting head MH31 of the third surface mounting equipment SMT3 is completed on the A2 substrate and the A2 substrate is converted into the A3 substrate, the A3 substrate may be moved for the next operation via the first transfer line L1.

Descriptions regarding the second mounting head MH12 of the first surface mounting equipment SMT1, the second mounting head MH22 of the second surface mounting equipment SMT2, and the second mounting head MH32 of the third surface mounting equipment SMT3 are similar to those provided above, one of ordinary skill in the art would readily understand such similarities.

The second surface mounting equipment SMT2 may include a first substrate sensor D21 and a second substrate sensor D22, the third surface mounting equipment SMT3 may include a first substrate sensor D31 and a second substrate sensor D32, and because their descriptions are similar to those regarding the first substrate sensor D11 and the second substrate sensor D12 of the first surface mounting equipment SMT1, one of ordinary skill in the art would readily understand such similarities.

Referring to FIGS. 7C and 7D, the surface mounting equipment may stop working due to malfunctions or errors. For example, the third surface mounting equipment SMT3 may stop working. The first mounting head MH31 and the second mounting head MH32 of the third surface mounting equipment SMT3 may be configured to perform mounting operations by using the A3 program and the B3 program. However, as the third surface mounting equipment SMT3 stops working, the main mounting operation by the first mounting head MH31 by using the A3 program and the main mounting operation by the second mounting head MH32 by using the B3 program may not be conducted.

The component mounting equipment 1 according to an example embodiment may transfer a main mounting operation program of halted surface mounting equipment to another component mounting equipment, enabling a main mounting operation of the paused surface mounting equipment to be performed in the component mounting equipment as the main mounting operation.

The detection of the halted surface mounting equipment may be enabled when a substrate, on which the operation is completed, is transferred within a minute. The duration for which the substrate is not transported may be appropriately set according to users. For example, as shown in FIG. 7C, because the operation of the third surface mounting equipment SMT3 has stopped, no compound mounting operation is conducted even though the A2 substrate reaches the front of the first mounting head MH31. When no operation is completed by the third surface mounting equipment SMT3 and a minute has passed, the main mounting program of the third surface mounting equipment SMT3 may be transmitted for preceding mounting.

For example, as shown in FIG. 7C, the A3 program, which is the main mounting program of the first mounting head MH31 of the third surface mounting equipment SMT3, may be transported to the third program PGM3 of the first mounting head MH21 of the second surface mounting equipment SMT2. That is, the first mounting head MH21 may be equipped with the first program PGM1, the second program PGM2, and the third program PGM3, wherein the first program PGM1 is the A2 program that is the main mounting program, the second program PGM2 is the B2 program that is the sub-mounting program, and the third program PGM3 is the A3 program that is an additional main mounting program.

When the A1 substrate reaches the first mounting head MH21, the first substrate sensor D21 may identify that the A1 substrate has reached. On the A1 substrate, the first mounting head MH21 may perform the component mounting operation by using the A2 program that is the main mounting program, and thus, the A1 substrate may be converted into the A2 substrate.

As shown in FIG. 7D, the first mounting head MH21 may not transport the A2 substrate to the next workstation and may continuously perform an additional main mounting operation thereon by using the A3 program that is the additional main mounting program. Therefore, as shown in FIG. 7E, the A2 substrate may be converted into the A3 substrate after the added main mounting operation using the A3 program. The A3 substrate is originally manufactured by the first mounting head MH31 of the third surface mounting equipment SMT3. However, as the third surface mounting equipment SMT3 stops working, the main mounting program of the third surface mounting equipment SMT3 is transmitted to the second surface mounting equipment SMT2, and thus, the operation intended for the third surface mounting equipment SMT3 is performed in the second surface mounting equipment SMT2.

Accordingly, the main mounting programs of two mounting heads of halted surface mounting equipment are transmitted and loaded onto previous surface mounting equipment, and the previous surface mounting equipment may be configured to perform the main mounting operation of the halted surface mounting equipment. The component mounting equipment 1 may enable, even when some of the surface mounting equipment stops operating, the entire operation to continue without interruption. Therefore, the component mounting equipment 1 according to this example embodiment may improve productivity of component mounting operation.

No operations are performed on the substrates having reached the third surface mounting equipment SMT3, the A2 substrate that has reached the front of the first mounting heads MH31 and the B2 substrate that has reached the front of the second mounting head MH32 may be transferred via the first transfer line and the second transfer line L2, respectively.

The first mounting head MH21 of the second surface mounting equipment SMT2 may perform not only the operation using the A2 program but also the operation using the A3 program of the first mounting head MH31 of the third surface mounting equipment SMT3. When two programs are used for the main mounting operation only in the second surface mounting equipment SMT2, in other surface mounting equipment, for example, in the first surface mounting equipment SMT1, one program is used for the main mounting operation, and thus, the time taken for the operation in the second surface mounting equipment SMT2 may be longer than that for the operation in the first surface mounting equipment SMT1.

When it is assumed that the time desired for the surface mounting operation using each program is generally consistent, the second surface mounting equipment SMT2 performs the main mounting operation twice, and thus, the operation time in the second surface mounting equipment SMT2 may be approximately twice as long as the time taken for the main mounting operation conducted once in the first surface mounting equipment SMT1. Therefore, a bottleneck in the component mounting operation on the substrate may occur in the second surface mounting equipment SMT2.

To alleviate the bottleneck in the second surface mounting equipment SMT2 caused by the halt of the third surface mounting equipment SMT3, the main mounting program of the second surface mounting equipment SMT2 may be transferred to the first surface mounting equipment SMT1 and loaded thereon. That is, although the second surface mounting equipment SMT2 has not stopped working, the main mounting program of the second surface mounting equipment SMT2 may be transferred to the first surface mounting equipment SMT1 and loaded thereon, similarly to the case where the shutdown of the third surface mounting equipment SMT3 leads to the transfer and loading of the main mounting program of the third surface mounting equipment SMT3 to the second surface mounting equipment SMT2.

As shown in FIG. 7C, for example, similar to the case where the A3 program, which is the main mounting program of the first mounting head MH31 of the third surface mounting equipment SMT3, is transferred to the first mounting head MH21 of the second surface mounting equipment SMT2 and loaded thereon, the A2 program, which is the main mounting program of the first mounting head MH21 of the second surface mounting equipment SMT2, may be transferred to the first surface mounting equipment SMT1 and loaded thereon.

As the A2 program is loaded on the first mounting head MH11 as the third program PGM3, the first mounting head MH11 may perform the main mounting operation on the A0 substrate by using the A1 program, which is the first program PGM1, to manufacture the A1 substrate, and may additionally perform the main mounting operation using the A2 program, which is the third program PGM3, on the A1 substrate to manufacture the A2 substrate.

It is described that the bottleneck may occur during the component mounting operation in the second surface mounting equipment SMT2 because the A1 substrate is converted into the A3 substrate using two programs in the second surface mounting equipment SMT2. However, when the main mounting program is transferred not only from the halted surface mounting equipment but also from the previous surface mounting equipment and loaded thereon, the occurrence of the bottleneck during the component mounting operation (e.g., the bottleneck possibly occurring in the previous surface mounting equipment rather than the halted surface mounting equipment) may be reduced.

For example, as the A2 program, which is the main mounting program of the second surface mounting equipment SMT2, is transferred to the first surface mounting equipment SMT1 and loaded thereon, the A0 substrate may be converted into the A2 substrate using the A1 program and the A2 program in the first surface mounting equipment SMT1 while the A1 substrate is changed to the A3 substrate using the A2 program and the A3 program in the second surface mounting equipment SMT2. While the second surface mounting equipment SMT2 performs the component mounting operations on substrates by using two programs, the first surface mounting equipment SMT1 may also perform the component mounting operations on the substrates by using two programs, and thus, there may not be a significant difference in the operation times in the second surface mounting equipment SMT2 and the first surface mounting equipment SMT1. Therefore, bottlenecks in the component mounting operations (e.g., the bottlenecks possibly occurring in surface mounting equipment immediately before the halted surface mounting equipment) may be reduced.

The component mounting equipment 1 may transfer and load the main mounting program of the halted surface mounting equipment to a previous surface mounting equipment. To this end, it may be possible to reduce production losses and continue the component mounting operations even though the surface mounting equipment stops working. Therefore, through the component mounting equipment 1 according to an example embodiment, the productivity of the component mounting operations may be improved.

Then, as in FIG. 7E, the A2 substrate and the B2 substrate, on which component mounting has been completed in the first surface mounting equipment SMT1, may be transferred to the second surface mounting equipment SMT2, and the A3 substrate and the B3 substrate, on which component mounting has been completed in the second surface mounting equipment SMT2, may pass through the third surface mounting equipment SMT3 and may be moved to the next surface mounting equipment or different equipment.

In other words, preceding mounting includes transferring and loading the main mounting program of the halted surface mounting equipment to the previous surface mounting equipment to continue the main mounting operation, which was performed in the halted surface mounting equipment.

Three pieces of surface mounting equipment are only shown in the drawing, but the surface mounting operations for components may be conducted using three or more pieces of surface mounting equipment. For example, the surface mounting operations may be continuously performed by ten pieces of surface mounting equipment. Because each surface mounting equipment handles different mounting operations, when one surface mounting equipment stops, operations by all the surface mounting equipment may not be implemented and may be congested.

The component mounting equipment 1 according to an example embodiment enables the component mounting operation of the halted surface mounting equipment to continue in other surface mounting equipment through the transfer of programs even though there is a halted surface mounting equipment. Therefore, the component mounting equipment 1 according to an example embodiment may have improved productivity of component mounting operation.

For example, when the third surface mounting equipment SMT3 halts, the second surface mounting equipment SMT2 and the first surface mounting equipment SMT1 may perform continuous mounting simultaneously with preceding mounting.

In other words, as the main mounting operation of the third surface mounting equipment SMT3 is performed as an additional main mounting operation in the second surface mounting equipment SMT2, when all of the main mounting operation and the additional main mounting operation by the first mounting head MH21 of the second surface mounting equipment SMT2 have been completed, the first mounting head MH21 may join the main mounting operation of the second mounting head MH22 as a sub-mounting head to perform the sub-mounting operation.

Because the main mounting operation by the second mounting head MH22 is performed using the B2 program, the first mounting head MH21 may join the second mounting head MH22 to perform the sub-mounting operation by using the B2 program that is the sub-mounting program of the first mounting head MH21. Similarly, the second mounting head MH22 serving as the main mounting head performs sequential mounting in cycle units, and the first mounting head MH21 serving as the sub-mounting head performs reverse mounting in cycle units.

However, because the additional main mounting operation added to the second mounting head MH22 is the mounting operation using the B3 program, when the second mounting head MH22 performs the additional main mounting operation using the B3 program, the first mounting head MH21 may not perform collaborative mounting. It is because the first mounting head MH21 is equipped with the A2 program as the main mounting program, the B2 program as the sub-mounting program, and the A3 program as the additional main mounting program.

Similarly, as the main mounting operation of the third surface mounting equipment SMT3 is performed in the second surface mounting equipment SMT2 as the additional main mounting operation, when all of the main mounting operation and the additional main mounting operation by the second mounting head MH22 of the second surface mounting equipment SMT2 have been completed, the second mounting head MH22 may join the main mounting operation of the first mounting head MH21 as the sub-mounting head to perform the sub-mounting operation. However, one of ordinary skill in the art would easily understand that the second mounting head MH22 may not join the additional main mounting operation of the first mounting head MH21, based on the descriptions above.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. Component mounting equipment comprising:
a first transfer line;
a second transfer line spaced apart from the first transfer line; and
a first surface mounting equipment on the first transfer line and the second transfer line,
wherein the first surface mounting equipment comprises a first mounting head that is adjacent to the first transfer line, a second mounting head that is adjacent to the second transfer line, and a first controller configured to control the first mounting head and the second mounting head,
the first controller is further configured to control the first surface mounting equipment to perform, in continuous mounting, either separate mounting or collaborative mounting while giving priority to the separate mounting,
the separate mounting is an operation in which each of the first mounting head and the second mounting head is configured to perform a main mounting operation on a main substrate,
the collaborative mounting is an operation in which one of the first mounting head or the second mounting head is configured to perform a main mounting operation on a single substrate, while the other one of the first mounting head or the second mounting head is configured to simultaneously perform a sub-mounting operation on the single substrate,
the main mounting operation is an operation in which the first mounting head is configured to perform an operation on a main substrate placed on the first transfer line or the second mounting head is configured to perform an operation on a main substrate placed on the second transfer line,
the sub-mounting operation is an operation in which the first mounting head is configured to perform an operation on a sub-substrate placed on the second transfer line or the second mounting head is configured to perform an operation on a sub-substrate placed on the first transfer line,
the main substrate comprises a substrate placed on the first transfer line with respect to the first mounting head or a substrate placed on the second transfer line with respect to the second mounting head, and
the sub-substrate comprises a substrate placed on the second transfer line with respect to the first mounting head or a substrate placed on the first transfer line with respect to the second mounting head.

2. The component mounting equipment of claim 1, wherein the first surface mounting equipment further comprises a first substrate sensor and a second substrate sensor,
the first substrate sensor is configured to identify, on the first transfer line, a substrate having reached a work area of the first mounting head, and
the second substrate sensor is configured to identify, on the second transfer line, a substrate having reached a work area of the second mounting head.

3. The component mounting equipment of claim 1, wherein each of the first mounting head and the second mounting head is equipped with at least two programs used to perform a component mounting operation,
the first mounting head is equipped with a main mounting program and a sub-mounting program, the second mounting head is equipped with a main mounting program and a sub-mounting program,
the main mounting program of the first mounting head comprises a program enabling the first mounting head to perform the main mounting operation on the main substrate, d
the main mounting program of the second mounting head comprises a program enabling the second mounting head to perform the main mounting operation on the main substrate,
the sub-mounting program of the first mounting head comprises a program enabling the first mounting head to perform the sub-mounting operation on the sub-substrate, and
the sub-mounting program of the second mounting head comprises a program enabling the second mounting head to perform the sub-mounting operation on the sub-substrate.

4. The component mounting equipment of claim 3, wherein the main mounting program of the first mounting head and the sub-mounting program of the second mounting head target a same substrate, and
the sub-mounting program of the first mounting head and the main mounting program of the second mounting head target a same substrate.

5. The component mounting equipment of claim 4, wherein the continuous mounting comprises an operation in which, when another substrate is introduced during the collaborative mounting on an existing substrate, a main mounting head configured to perform the main mounting operation on the another substrate is configured to stop the sub-mounting operation on the existing substrate and perform the main mounting operation on the other substrate.

6. The component mounting equipment of claim 5, wherein the continuous mounting comprises an operation in which, when the main mounting operation by any one of the first mounting head and the second mounting head is completed during the separate mounting, the mounting head which has completed the main mounting operation is configured to join the main mounting operation of the other of the first mounting head and the second mounting head and perform the sub-mounting operation.

7. The component mounting equipment of claim 5, wherein the main mounting operation and the sub-mounting operation are configured to be performed in cycle units, and
a cycle is one of a plurality of cycles for grouping components mounted on a specific substrate when the main mounting operation or the sub-mounting operation is performed on the specific substrate by using one program.

8. The component mounting equipment of claim 7, wherein, in the plurality of cycles, the main mounting head is configured to perform sequential mounting in the cycle units from earlier-numbered cycles among the plurality of cycles,
a sub-mounting head is configured to perform reverse mounting in the cycle units from later-numbered cycles among the plurality of cycles, and
an order of cycles in which the reverse mounting is executed is opposite to an order of cycles in which the sequential mounting is executed.

9. The component mounting equipment of claim 8, wherein a manner, in which components are grouped into the plurality of cycles, comprises dividing the components based on a first virtual central line in a same direction as the first transfer line or the second transfer line and grouping, with respect to the first virtual central line, components relatively close to the main mounting head into the earlier-numbered cycles and components relatively close to the sub-mounting head into the later-numbered cycles.

10. The component mounting equipment of claim 7, wherein the main mounting head is configured to perform a mounting operation from a cycle relatively close to the main mounting head among the plurality of cycles, and a sub-mounting head configured to perform the sub-mounting operation is configured to perform a mounting operation from a cycle relatively close to the sub-mounting head among the plurality of cycles.

11. The component mounting equipment of claim 7, wherein a number of components picked up by each of the first mounting head and the second mounting head for mounting operations is same as a number of components in each of the plurality of cycles.

12. The component mounting equipment of claim 4, further comprising:
a second surface mounting equipment placed on the first transfer line and the second transfer line, the second surface mounting equipment arranged next to the first surface mounting equipment,
wherein the second surface mounting equipment comprises a first mounting head that is adjacent to the first transfer line, a second mounting head that is adjacent to the second transfer line, and a second controller configured to control the first mounting head and the second mounting head,
when the second surface mounting equipment stops working, the first controller is configured to control the first surface mounting equipment to perform preceding mounting, and
the preceding mounting is performed by the first mounting head of the first surface mounting equipment as a main mounting operation to which a main mounting operation of the first mounting head of the second surface mounting equipment is added.

13. The component mounting equipment of claim 12, wherein, when the second surface mounting equipment stops working, a main mounting program of the first mounting head of the second surface mounting equipment is transferred to the first mounting head of the first surface mounting equipment as an additional main mounting program and loaded on the first mounting head of the first surface mounting equipment.

14. The component mounting equipment of claim 12, wherein the second controller is further configured to:
determine that the second surface mounting equipment stops working when an output from a component mounting operation of the second surface mounting equipment is not transferred within a minute; and
transmit, to the first controller, a state in which the second surface mounting equipment stops working.

15. The component mounting equipment of claim 13, wherein a substrate, on which the main mounting program and the additional main mounting program are completely executed by the first mounting head in the first surface mounting equipment, is not configured to be processed in the second surface mounting equipment and pass the second surface mounting equipment.

16. The component mounting equipment of claim 15, wherein the preceding mounting further comprises allowing a main mounting operation of the second mounting head of the second surface mounting equipment to be performed by the second mounting head of the first surface mounting equipment as an additional main mounting operation,
a main mounting program of the second mounting head of the second surface mounting equipment is transferred to the second mounting head of the first surface mounting equipment as an additional main mounting program and loaded on the second mounting head of the first surface mounting equipment, and
a substrate, on which the main mounting operation and the additional main mounting operation are completed by the second mounting head in the first surface mounting equipment, is not configured to be processed in the second surface mounting equipment and pass the second surface mounting equipment.

17. Component mounting equipment comprising:
a first transfer line;
a second transfer line parallel to the first transfer line, the second transfer line being separate from the first transfer line in a lateral direction;
a first surface mounting equipment on the first transfer line and the second transfer line; and
a second surface mounting equipment on the first transfer line and the second transfer line, the second surface mounting equipment being next to the first surface mounting equipment,
wherein the first surface mounting equipment comprises a first mounting head that is adjacent to the first transfer line, a second mounting head that is adjacent to the second transfer line, and a first controller configured to control the first mounting head and the second mounting head of the first surface mounting equipment,
the second surface mounting equipment comprises a first mounting head that is adjacent to the first transfer line, a second mounting head that is adjacent to the second transfer line, and a second controller configured to control the first mounting head and the second mounting head of the second surface mounting equipment,
when the second surface mounting equipment stops working, the first controller is further configured to control the first surface mounting equipment to perform preceding mounting,
the preceding mounting is performed by the first mounting head of the first surface mounting equipment as a main mounting operation to which a main mounting operation of the first mounting head of the second surface mounting equipment is added, and
the main mounting operation comprises an operation in which the first mounting head of the first surface mounting equipment or the first mounting head of the second surface mounting equipment performs an operation on a main substrate placed on the first transfer line or an operation in which the second mounting head of the first surface mounting equipment or the second mounting head of the second surface mounting equipment performs an operation on a main substrate placed on the second transfer line.

18. The component mounting equipment of claim 17, wherein, when the second surface mounting equipment stops working, a main mounting program of the first mounting head of the second surface mounting equipment is transferred and loaded onto the first mounting head of the first surface mounting equipment as an additional main mounting program,
the second controller is further configured to determine that the second surface mounting equipment has stopped working when an output from a component mounting operation of the second surface mounting equipment is not transferred within a minute,
the second controller is further configured to transmit, to the first controller, a state in which the second surface mounting equipment has stopped working, and
a substrate, on which the main mounting operation and the additional main mounting operation are completed by the first mounting head in the first surface mounting equipment, is not processed in the second surface mounting equipment and passes the second surface mounting equipment.

19. The component mounting equipment of claim 18, wherein the first controller is further configured to control the first surface mounting equipment so that the first surface mounting equipment performs an operation comprising continuous mounting,
in the continuous mounting, the first surface mounting equipment is configured to perform either separate mounting or collaborative mounting while giving priority to the separate mounting,
the separate mounting is an operation in which each of the first mounting head and the second mounting head of the first surface mounting equipment is configured to perform a main mounting operation on a main substrate,
the collaborative mounting is an operation in which one of the first mounting head or the second mounting head in the first surface mounting equipment is configured to perform a main mounting operation on a main substrate, while the other one of the first mounting head or the second mounting head in the first surface mounting equipment is configured to simultaneously perform a sub-mounting operation on a sub-substrate,
the main mounting operation is an operation in which the first mounting head of the first surface mounting equipment is configured to perform an operation on a main substrate placed on the first transfer line or the second mounting head is configured to perform an operation on a main substrate placed on the second transfer line,
the sub-mounting operation is an operation in which the first mounting head of the first surface mounting equipment is configured to perform an operation on a sub-substrate placed on the second transfer line or the second mounting head is configured to perform an operation on a sub-substrate placed on the first transfer line,
the main substrate comprises a substrate placed on the first transfer line with respect to the first mounting head of the first surface mounting equipment or a substrate placed on the second transfer line with respect to the second mounting head of the first surface mounting equipment, and
the sub-substrate comprises a substrate placed on the second transfer line with respect to the first mounting head of the first surface mounting equipment or a substrate placed on the first transfer line with respect to the second mounting head of the first surface mounting equipment.

20. Component mounting equipment comprising:
a first transfer line;
a second transfer line parallel to the first transfer line, the second transfer line being separate from the first transfer line in a lateral direction;
a first surface mounting equipment on the first transfer line and the second transfer line; and
a second surface mounting equipment on the first transfer line and the second transfer line, the second surface mounting equipment being next to the first surface mounting equipment,
wherein the first surface mounting equipment comprises a first mounting head that is adjacent to the first transfer line, a second mounting head that is adjacent to the second transfer line, and a first controller configured to control the first mounting head and the second mounting head of the first surface mounting equipment,
the second surface mounting equipment comprises a first mounting head that is adjacent to the first transfer line, a second mounting head that is adjacent to the second transfer line, and a second controller configured to control the first mounting head and the second mounting head of the second surface mounting equipment,
the first controller is further configured to control the first surface mounting equipment so that the first surface mounting equipment performs an operation comprising continuous mounting,
when the second surface mounting equipment stops working, the first controller is further configured to control the first surface mounting equipment to perform preceding mounting,
in the continuous mounting, the first surface mounting equipment is configured to perform either separate mounting or collaborative mounting while giving priority to the separate mounting,
the separate mounting is an operation in which each of the first mounting head and the second mounting head is configured to perform a main mounting operation on a main substrate,
the collaborative mounting is an operation in which one of the first mounting head and the second mounting head is configured to perform a main mounting operation on a main substrate, while the other one of the first mounting head and the second mounting head is configured to simultaneously perform a sub-mounting operation on a sub-substrate,
the preceding mounting is performed by the first mounting head of the first surface mounting equipment as a main mounting operation to which a main mounting operation of the first mounting head of the second surface mounting equipment is added,
the main mounting operation is an operation in which the first mounting head of the first surface mounting equipment or the first mounting head of the second surface mounting equipment is configured to perform an operation on a main substrate placed on the first transfer line or the second mounting head of the first surface mounting equipment or the second mounting head of the second surface mounting equipment is configured to perform an operation on a main substrate placed on the second transfer line,
the sub-mounting operation is an operation in which the first mounting head of the first surface mounting equipment or the first mounting head of the second surface mounting equipment is configured to perform an operation on a sub-substrate placed on the second transfer line or the second mounting head of the first surface mounting equipment or the second mounting head of the second surface mounting equipment is configured to perform an operation on a sub-substrate placed on the first transfer line,
the main substrate comprises a substrate placed on the first transfer line with respect to the first mounting head or on the second transfer line with respect to the second mounting head, and
the sub-substrate comprises a substrate placed on the second transfer line with respect to the first mounting head or a substrate placed on the first transfer line with respect to the second mounting head.
